(19) United States
(12) Patent Application Publication
(10) Pub. No.: US 2024/0143894 A1
(43) Pub. Date: May 2, 2024

(54) SYSTEM AND METHOD FOR QUANTUM CIRCUIT DESIGN FOR DECISION AND CLASSIFICATION PROBLEMS

(71) Applicant: IonQ, Inc., College Park, MD (US)

(72) Inventors: Dominic WIDDOWS, Bellevue, WA (US); Peter CHAPMAN, North Bend, WA (US)

(21) Appl. No.: 18/493,440

(22) Filed: Oct. 24, 2023

Related U.S. Application Data
(60) Provisional application No. 63/381,083, filed on Oct. 26, 2022.

(51) Int. Cl. G06F 30/398; G06N 10/40

(52) U.S. Cl. CPC G06F 30/398; G06N 10/40

(57) ABSTRACT

Aspects of the present disclosure relate generally to systems and methods for use in the implementation and/or operation of quantum information processing (QIP) systems, and more particularly, to systems and methods for designing and configuring a quantum circuit to implement a solution to classification and decision problems.

### CROSS-REFERENCE TO RELATED APPLICATIONS

This application is claims the benefit of U.S. Provisional Application No. 63/381,083, filed Oct. 26, 2022, which is herein incorporated by reference in its entirety.

### TECHNICAL FIELD

Aspects of the present disclosure relate generally to systems and methods for use in the implementation and/or operation of quantum information processing (QIP) systems.

### BACKGROUND

Trapped atoms are one of the leading implementations for quantum information processing or quantum computing. Atomic-based qubits may be used as quantum memories, as quantum gates in quantum computers and simulators, and may act as nodes for quantum communication networks. Qubits based on trapped atomic ions enjoy a rare combination of attributes. For example, qubits based on trapped atomic ions have very good coherence properties, may be prepared and measured with nearly 100% efficiency, and are readily entangled with each other by modulating their Coulomb interaction with suitable external control fields such as optical or microwave fields. These attributes make atomic-based qubits attractive for extended quantum operations such as quantum computations or quantum simulations.

It is therefore important to develop new techniques that improve the design, fabrication, implementation, and/or control of different QIP systems used as quantum computers or quantum simulators, and particularly for those QIP systems that implement quantum circuits that handle operations based on atomic-based qubits.

### SUMMARY

The following presents a simplified summary of one or more aspects to provide a basic understanding of such aspects. This summary is not an extensive overview of all contemplated aspects and is intended to neither identify key or critical elements of all aspects nor delineate the scope of any or all aspects. Its sole purpose is to present some concepts of one or more aspects in a simplified form as a prelude to the more detailed description that is presented later.

In some aspects, the techniques described herein relate to a method for configuring a quantum circuit having a plurality of qubits to implement classification, the method including: receiving training data including a plurality of text inputs and corresponding class labels, wherein each text input includes a plurality of words; determining, for each respective word in the plurality of text inputs, a weight value of the respective word relative to each of the corresponding class labels; configuring a plurality of gates in the quantum circuit to rotate the plurality of qubits, wherein each qubit represents a combination of a word in the plurality of text inputs and a class label of the corresponding class labels, and wherein configuring the plurality of gates includes fixing, for each of the plurality of qubits, an angle between two pairs of axes based on a determined weight value corresponding to the word and the class label; and configuring the quantum circuit to (1) connect gates in the plurality of gates based on words in an input classification query and (2) generate an output class label for the input classification query.

In some aspects, the techniques described herein relate to a quantum information processing (QIP) system including: at least one memory; and at least one hardware processor coupled with the at least one memory and configured, individually or in combination, to: receive training data including a plurality of text inputs and corresponding class labels, wherein each text input includes a plurality of words; determine, for each respective word in the plurality of text inputs, a weight value of the respective word relative to each of the corresponding class labels; configure a plurality of gates in a quantum circuit to rotate a plurality of qubits, wherein each qubit represents a combination of a word in the plurality of text inputs and a class label of the corresponding class labels, and wherein configuring the plurality of gates includes fixing, for each of the plurality of qubits, an angle between two pairs of axes based on a determined weight value corresponding to the word and the class label; and configure the quantum circuit to (1) connect gates in the plurality of gates based on words in an input classification query and (2) generate an output class label for the input classification query.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

The disclosed aspects will hereinafter be described in conjunction with the appended drawings, provided to illustrate and not to limit the disclosed aspects, wherein like designations denote like elements, and in which:

FIG. 1 illustrates a view of atomic ions a linear crystal or chain in accordance with aspects of this disclosure.

FIG. 2 illustrates an example of a quantum information processing (QIP) system in accordance with aspects of this disclosure.

FIG. 3 illustrates an example of a computer device in accordance with aspects of this disclosure.

FIG. 4A illustrates an exemplary adder circuit in accordance with aspects of this disclosure.

FIG. 4B illustrates an X-rotation applied to a qubit in accordance with aspects of this disclosure.

FIG. 5 illustrates a circuit for analyzing training data for generating the quantum circuit in accordance with aspects of this disclosure.

FIG. 6 illustrates a decision tree in accordance with aspects of this disclosure.

FIGS. 7A and 7B illustrate example quantum circuit implementations of Boolean connectives in accordance with aspects of this disclosure.

FIG. 8 illustrates a quantum circuit that implements the “Play Tennis” decision tree in accordance with aspects of this disclosure.

FIG. 9 illustrates an example quantum circuit for a superposition of conjunctions classifier in accordance with aspects of this disclosure.

FIG. 10 illustrates an example implementation for a conditional expression in accordance with aspects of this disclosure.

FIG. 11 illustrates a method for configuring a quantum circuit comprising a plurality of qubits to implement classification in accordance with aspects of this disclosure.

### DETAILED DESCRIPTION

The detailed description set forth below in connection with the appended drawings or figures is intended as a description of various configurations or implementations and is not intended to represent the only configurations or implementations in which the concepts described herein may be practiced. The detailed description includes specific details for the purpose of providing a thorough understanding of various concepts. However, it will be apparent to those skilled in the art that these concepts may be practiced without these specific details or with variations of these specific details. In some instances, well known components are shown in block diagram form, while some blocks may be representative of one or more well-known components.

The present disclosure describes various aspects of systems and methods for the designing and configuration of quantum circuits that implement solutions to classification and decision problems. In an exemplary aspect, the system and method described herein is configured to design a quantum circuit by assigning specific roles to qubits in the quantum circuit, such that they individually represent known input values, output observations, and/or intermediate variables. For example, each of the target classes or labels may have a classification qubit, arranged so that the chance of observing a |1> for the qubit increases with the probability of this qubit representing the correct class label. To do so, the system and method are configured to partially rotate gates of the quantum circuit in order to represent different weights of individual features or combinations of features. In an exemplary aspect, the use of controlled gates by the system and method, include, but are not limited to, CNOT gates, Toffoli gates, and variations of these gates to combine values and accumulate the contributions from different signals.

In general, a “bag-of-words” model is a simplifying representation used in natural language processing and information retrieval. In this model, a text (such as a sentence or a document) is represented as the bag (e.g., the multiset) of its words, disregarding grammar and even word order, but keeping multiplicity. The bag-of-words model may address problems, such as assigning topic labels to text, and addressing problems, such as a question: “should we play tennis?” as a decision problem, all of which may be viewed as “choose one of these options” classification problems.

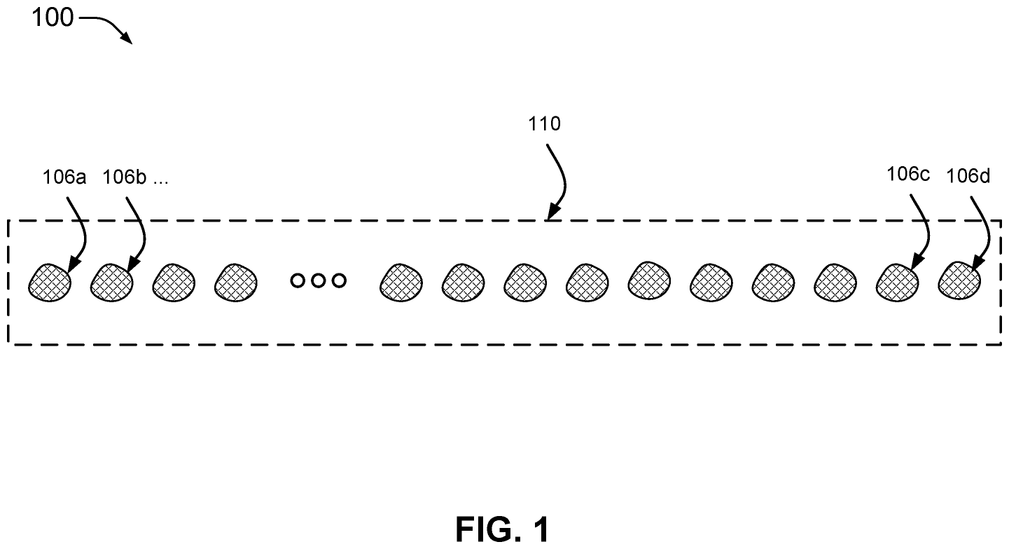

In view of the bag-of-word model, a system and method is disclosed herein for generating and/or configuring quantum circuits that implement solutions to classification and decision problems, such that the implemented solutions may be executed on gate-based quantum computers. Solutions to the issues described above are explained in more detail in connection with FIGS. 1-10, with FIGS. 1-3 providing a background of QIP systems or quantum computers, and more specifically, of atomic-based QIP systems or quantum computers configured to implement the systems and methods described herein.

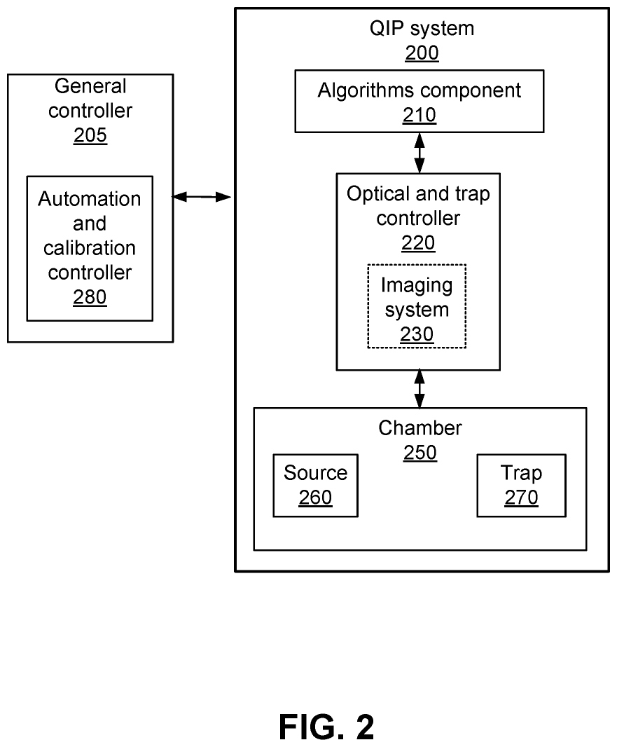

FIG. 1 illustrates a diagram 100 with multiple atomic ions or ions 106 (e.g., ions 106a, 106b, . . . , 106c, and 106d) trapped in a linear crystal or chain 110 using a trap (not shown; the trap may be inside a vacuum chamber as shown in FIG. 2). The trap maybe referred to as an ion trap. The ion trap shown may be built or fabricated on a semiconductor substrate, a dielectric substrate, or a glass die or wafer (also referred to as a glass substrate). The ions 106 may be provided to the trap as atomic species for ionization and confinement into the chain 110. Some or all of the ions 106 may be configured to operate as qubits in a QIP system.

In the example shown in FIG. 1, the trap includes electrodes for trapping or confining multiple ions into the chain 110 laser-cooled to be nearly at rest. The number of ions trapped may be configurable and more or fewer ions may be trapped. The ions may be Ytterbium ions (e.g., ¹⁷¹Yb⁺ ions), for example. The ions are illuminated with laser (optical) radiation tuned to a resonance in ¹⁷¹Yb⁺ and the fluorescence of the ions is imaged onto a camera or some other type of detection device (e.g., photomultiplier tube or PMT). In this example, ions may be separated by a few microns (m) from each other, although the separation may vary based on architectural configuration. The separation of the ions is determined by a balance between the external confinement force and Coulomb repulsion and does not need to be uniform. Moreover, in addition to Ytterbium ions, neutral atoms, Rydberg atoms, or other types of atomic-based qubit technologies may also be used. Moreover, ions of the same species, ions of different species, and/or different isotopes of ions may be used. The trap may be a linear RF Paul trap, but other types of confinement devices may also be used, including optical confinements. Thus, a confinement device may be based on different techniques and may hold ions, neutral atoms, or Rydberg atoms, for example, with an ion trap being one example of such a confinement device. The ion trap may be a surface trap, for example.

FIG. 2 illustrates a block diagram that shows an example of a QIP system 200. The QIP system 200 may also be referred to as a quantum computing system, a quantum computer, a computer device, a trapped ion system, or the like. The QIP system 200 may be part of a hybrid computing system in which the QIP system 200 is used to perform quantum computations and operations and the hybrid computing system also includes a classical computer to perform classical computations and operations. The quantum and classical computations and operations may interact in such a hybrid system.

Shown in FIG. 2 is a general controller 205 configured to perform various control operations of the QIP system 200. These control operations may be performed by an operator, may be automated, or a combination of both. Instructions for at least some of the control operations may be stored in memory (not shown) in the general controller 205 and may be updated over time through a communications interface (not shown). Although the general controller 205 is shown separate from the QIP system 200, the general controller 205 may be integrated with or be part of the QIP system 200. The general controller 205 may include an automation and calibration controller 280 configured to perform various calibration, testing, and automation operations associated with the QIP system 200. These calibration, testing, and automation operations may involve, for example, all or part of an algorithms component 210, all or part of an optical and trap controller 220 and/or all or part of a chamber 250.

The QIP system 200 may include the algorithms component 210 mentioned above, which may operate with other parts of the QIP system 200 to perform or implement quantum algorithms, quantum applications, or quantum operations. The algorithms component 210 may be used to perform or implement a stack or sequence of combinations of single qubit operations and/or multi-qubit operations (e.g., two-qubit operations) as well as extended quantum computations. The algorithms component 210 may also include software tools (e.g., compilers) that facility such performance or implementation. As such, the algorithms component 210 may provide, directly or indirectly, instructions to various components of the QIP system 200 (e.g., to the optical and trap controller 220) to enable the performance or implementation of the quantum algorithms, quantum applications, or quantum operations. The algorithms component 210 may receive information resulting from the performance or implementation of the quantum algorithms, quantum applications, or quantum operations and may process the information and/or transfer the information to another component of the QIP system 200 or to another device (e.g., an external device connected to the QIP system 200) for further processing.

The QIP system 200 may include the optical and trap controller 220 mentioned above, which controls various aspects of a trap 270 in the chamber 250, including the generation of signals to control the trap 270. The optical and trap controller 220 may also control the operation of lasers, optical systems, and optical components that are used to provide the optical beams that interact with the atoms or ions in the trap. Optical systems that include multiple components may be referred to as optical assemblies. The optical beams are used to set up the ions, to perform or implement quantum algorithms, quantum applications, or quantum operations with the ions, and to read results from the ions. Control of the operations of laser, optical systems, and optical components may include dynamically changing operational parameters and/or configurations, including controlling positioning using motorized mounts or holders. When used to confine or trap ions, the trap 270 may be referred to as an ion trap. The trap 270, however, may also be used to trap neutral atoms, Rydberg atoms, and other types of atomic-based qubits. The optical sources for the lasers, optical systems, and optical components may be at least partially located in the optical and trap controller 220, an imaging system 230, and/or in the chamber 250.

The QIP system 200 may include the imaging system 230. The imaging system 230 may include a high-resolution imager (e.g., CCD camera) or other type of detection device (e.g., PMT) for monitoring the ions while they are being provided to the trap 270 and/or after they have been provided to the trap 270 (e.g., to read results). In an aspect, the imaging system 230 may be implemented separate from the optical and trap controller 220, however, the use of fluorescence to detect, identify, and label ions using image processing algorithms may need to be coordinated with the optical and trap controller 220.

In addition to the components described above, the QIP system 200 may include a source 260 that provides atomic species (e.g., a plume or flux of neutral atoms) to the chamber 250 having the trap 270. When atomic ions are the basis of the quantum operations, that trap 270 confines the atomic species once ionized (e.g., photoionized). The trap 270 may be part of what may be referred to as a processor or processing portion of the QIP system 200. That is, the trap 270 may be considered at the core of the processing operations of the QIP system 200 since it holds the atomic-based qubits that are used to perform or implement the quantum operations or simulations. At least a portion of the source 260 may be implemented separate from the chamber 250.

It is to be understood that the various components of the QIP system 200 described in FIG. 2 are described at a high-level for ease of understanding. Such components may include one or more sub-components, the details of which may be provided below as needed to better understand certain aspects of this disclosure.

Aspects of this disclosure may be implemented at least partially using the QIP system 200 with the optical elements of a beam shaping structure as arranged therein.

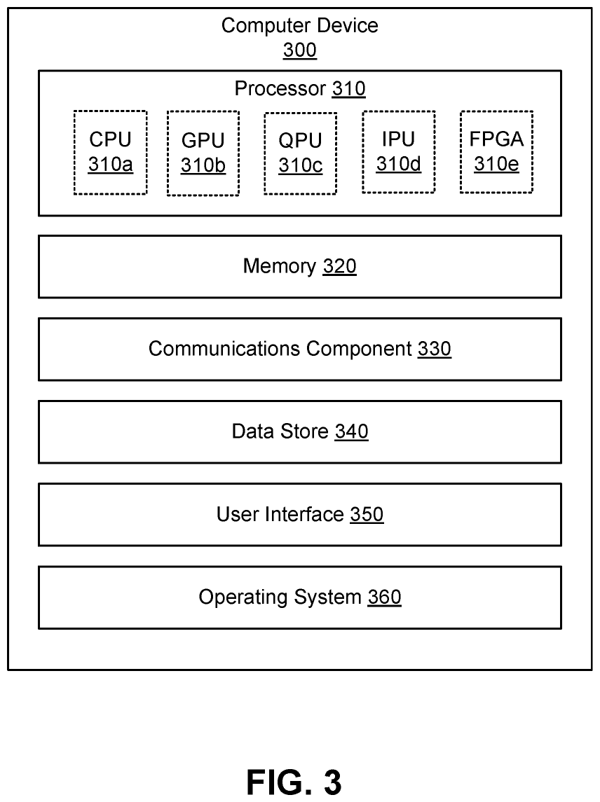

Referring now to FIG. 3, an example of a computer system or device 300 is shown. The computer device 300 may represent a single computing device, multiple computing devices, or a distributed computing system, for example. The computer device 300 may be configured as a quantum computer (e.g., a QIP system), a classical computer, or to perform a combination of quantum and classical computing functions, sometimes referred to as hybrid functions or operations. For example, the computer device 300 may be used to process information using quantum algorithms, classical computer data processing operations, or a combination of both. In some instances, results from one set of operations (e.g., quantum algorithms) are shared with another set of operations (e.g., classical computer data processing). A generic example of the computer device 300 implemented as a QIP system capable of performing quantum computations and simulations is, for example, the QIP system 200 shown in FIG. 2.

The computer device 300 may include a processor 310 for carrying out processing functions associated with one or more of the features described herein. The processor 310 may include a single processor, multiple set of processors, or one or more multi-core processors. Moreover, the processor 310 may be implemented as an integrated processing system and/or a distributed processing system. The processor 310 may include one or more central processing units (CPUs) 310a, one or more graphics processing units (GPUs) 310b, one or more quantum processing units (QPUs) 310c, one or more intelligence processing units (IPUs) 310d (e.g., artificial intelligence or AI processors), one or more field-programmable gate arrays (FPGAs) 310e, or a combination of some or all those types of processors. In one aspect, the processor 310 may refer to a general processor of the computer device 300, which may also include additional processors 310 to perform more specific functions (e.g., including functions to control the operation of the computer device 300). Quantum operations may be performed by the QPUs 310c. Some or all of the QPUs 310c may use atomic-based qubits, however, it is possible that different QPUs are based on different qubit technologies.

The computer device 300 may include a memory 320 for storing instructions executable by the processor 310 to carry out operations. The memory 320 may also store data for processing by the processor 310 and/or data resulting from processing by the processor 310. In an implementation, for example, the memory 320 may correspond to a computer-readable storage medium that stores code or instructions to perform one or more functions or operations. Just like the processor 310, the memory 320 may refer to a general memory of the computer device 300, which may also include additional memories 320 to store instructions and/or data for more specific functions.

It is to be understood that the processor 310 and the memory 320 may be used in connection with different operations including but not limited to computations, calculations, simulations, controls, calibrations, system management, and other operations of the computer device 300, including any methods or processes described herein.

Further, the computer device 300 may include a communications component 330 that provides for establishing and maintaining communications with one or more parties utilizing hardware, software, and services. The communications component 330 may also be used to carry communications between components on the computer device 300, as well as between the computer device 300 and external devices, such as devices located across a communications network and/or devices serially or locally connected to computer device 300. For example, the communications component 330 may include one or more buses, and may further include transmit chain components and receive chain components associated with a transmitter and receiver, respectively, operable for interfacing with external devices. The communications component 330 may be used to receive updated information for the operation or functionality of the computer device 300.

Additionally, the computer device 300 may include a data store 340, which may be any suitable combination of hardware and/or software, which provides for mass storage of information, databases, and programs employed in connection with the operation of the computer device 300 and/or any methods or processes described herein. For example, the data store 340 may be a data repository for operating system 360 (e.g., classical OS, or quantum OS, or both). In one implementation, the data store 340 may include the memory 320. In an implementation, the processor 310 may execute the operating system 360 and/or applications or programs, and the memory 320 or the data store 340 may store them.

The computer device 300 may also include a user interface component 350 configured to receive inputs from a user of the computer device 300 and further configured to generate outputs for presentation to the user or to provide to a different system (directly or indirectly). The user interface component 350 may include one or more input devices, including but not limited to a keyboard, a number pad, a mouse, a touch-sensitive display, a digitizer, a navigation key, a function key, a microphone, a voice recognition component, any other mechanism capable of receiving an input from a user, or any combination thereof. Further, the user interface component 350 may include one or more output devices, including but not limited to a display, a speaker, a haptic feedback mechanism, a printer, any other mechanism capable of presenting an output to a user, or any combination thereof. In an implementation, the user interface component 350 may transmit and/or receive messages corresponding to the operation of the operating system 360. When the computer device 300 is implemented as part of a cloud-based infrastructure solution, the user interface component 350 may be used to allow a user of the cloud-based infrastructure solution to remotely interact with the computer device 300.

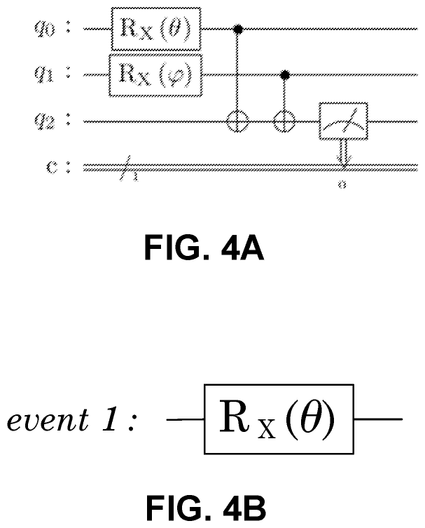

In connection with the systems described in FIGS. 1-3, and with further details provided in FIGS. 4-10 below, the present disclosure provides various aspects of techniques for quantum circuit design and configuration that accurately implements a gate-based solution to classification and decision problems. In general, classification and decision problems may be considered decisions one may make and a choice selection between a limited set of options, such as “should I play tennis?” (the play tennis decision discussed below). In other words, this is a classification problem and the system and method described herein may be configured to generate a quantum circuit configured to generate a solution or outcome based on variable input data, with the gates of the quantum circuit configured to accurately determine a class label.

In one exemplary aspect, computer device 300 configures a quantum circuit having a plurality of qubits to implement a solution to classification and decision problems. In particular, computer device 300 may receive a plurality of training data and store the data in data store 340. Computer device 300 may determine, using processor 310, a plurality of weight values based on an analysis of the training data including determining a number of words in the training data. Computer device 300 may configure a plurality of gates in a quantum circuit by applying one or more lasers, for example, generated by an optical source of the optical and trap controller 220, in Raman configuration of a quantum computer to rotate the plurality of qubits based on the plurality of weight values, respectively, to fix an angle between two pairs of axes for each of the plurality of qubits. Computer device 300 may further configure the quantum circuit to connect the plurality of gates such that an outcome of a single classification problem makes an output of a subsequent event more or less likely.

In particular, the system and method of an exemplary aspect includes computer device 300 configured to design and/or configure a quantum circuit by assigning specific roles to qubits in the quantum circuit, such that they individually represent input known values, output observations, and/or intermediate variables. For example, each of the target classes or labels may have a classification qubit, arranged so that the chance of observing a |1> of the classification qubit increases with the probability of this qubit representing the correct class label. Moreover, computer device 300 is configured to partially rotate gates of the quantum circuit in order to represent the different weights of individual features or combinations of features. In an exemplary aspect, the use of controlled gates by the system and method, include, but are not limited to, CNOT gates, Toffoli gates, and variations of these gates to combine values and accumulate the contributions from different signals.

Thus, in an exemplary aspect, computer device 300 is configured to generate and/or configure a quantum circuit that accurately implements a gate-based solution to classification and decision problems. For example, the quantum circuit may be configured to rotates gates therein as single-word features in a “bag-of-words” classifier circuit, where the amount of rotations may be based on training data relating to the classification. The combination of such features using quantum gates enables the implementation of Boolean logic operations.

In an exemplary aspect, computer device 300 may be configured to use fractional rotations in multi-qubit controlled gates. As a result, this configuration provides that combinations of features may have a weighted behavior that is distinct from the individual feature weighting used in the bag-of-words classification.

Moreover, in an exemplary aspect, computer device 300 may be configured using the techniques described herein to “compile” a learned decision tree into the quantum circuit that implements the same logic of the decision tree. In one aspect, such a decision circuit may be trained by computer device 300 directly from the same input examples used to train the classical decision tree. Effectively, computer device 300 may bypass the need for training that relies on a traditional classical algorithm. In addition, computer device 300 enables the classifier to be trained incrementally when new examples are introduced, in an “online” fashion, such that the classifier may be dynamically updated. This may be referred to as a “superposition of conjunctions” and reproduces results on the training data exactly. The superposition of conjunctions method may also be extended with partial conjunctions in an exemplary aspect, such that the resulting circuits perform better than the sklearn decision tree implementation.

FIG. 4A illustrates an exemplary adder circuit. According to an exemplary aspect, a key building block is an “adder circuit,” which uses CNOT gates to combine two partial rotations (in qubits q0, q1) into a “sum” qubit (e.g., q2). As shown, the first qubit q0 is rotated through angle θ, which may be a large angle (e.g., indicating that the corresponding feature is very pertinent to the classification). The next qubit q1 may be rotated by angle φ, which may be a relatively smaller angle because the feature should be weighted less.

Thus, computer device 300 may be configured to apply a single-qubit rotation to set the appropriate output probability. In other words, particular rotations and ranges may be defined by the quantum system (e.g., as described above for FIGS. 2 and 3) for angle θ and φ—defining the amount of X-rotation for qubits q0 and q1. That is, each qubit q0 to q2 may be implemented as a gate in the quantum circuit. These gates may be combined as a small recipe for adding up classifier weights to combine two or more stimuli (e.g., data inputs for the classification). Using these tiny recipes, computer device 300 may be configured to build a classifier circuit by taking a complete collection of training data. These recipes effectively configure the circuit to use each bit of training data to build the larger classifier circuit.

As described above, the systems and methods described herein are configured to implement a quantum circuit for implementing a gate-based solution to classification and decision problems and may be executed on a gate-based quantum computer in an exemplary aspect. For example, a native gate set is a set of quantum gates that may be physically executed on hardware computing systems (e.g., FIGS. 2-3) by addressing ions (e.g., FIG. 1) with resonant lasers (e.g., generated by an optical source of the optical and trap controller 220) via stimulated Raman transitions. The angles θ and φ may be defined by the amount of X-rotation where single-qubit gates may be rotated along different axes on a Bloch sphere and/or as rotations along a fixed axis while rotating the Bloch sphere itself. In an exemplary aspect, the rotations may be physically implemented as Rabi oscillations that are made with a two-photon Raman transition, i.e., driving the qubits, as shown in FIG. 1, for example, on resonance using a pair of lasers in a Raman configuration. Moreover, the ranges may be controlled by varying the duration of the laser pulses of the Raman configuration.

In another exemplary aspect, FIG. 4B illustrates an X-rotation that is applied where the angle θ is defined as follows according to the following equation:

cos²(θ)=P(A)⇒θ=arccos\sqrt{P(A)}

According to this configuration, computer device 300 is configured to determine the appropriate angle (e.g., angle θ) to model each word with the appropriate weighting factor values, which may be based on training data according to an exemplary aspect. In addition, quantum computing uses complex coordinates, which adds a critical dimension. In an exemplary aspect, instead of being predicted by a single angle θ, each question vector preferably has a phase angle φ, and an appropriate combination of rotations may be used to generate any of these states. It should be appreciated that while “words” that are modeled can be derived, for example, by a document(s) prepared by a user, the words can more generically be considered as any type of automatically generated word, such as an input from a sensor. For example, a thermometer may generally output “texts” that could be “hot”, “warm” or “cold” and then modeling could be based on such inputs according to an exemplary aspect.

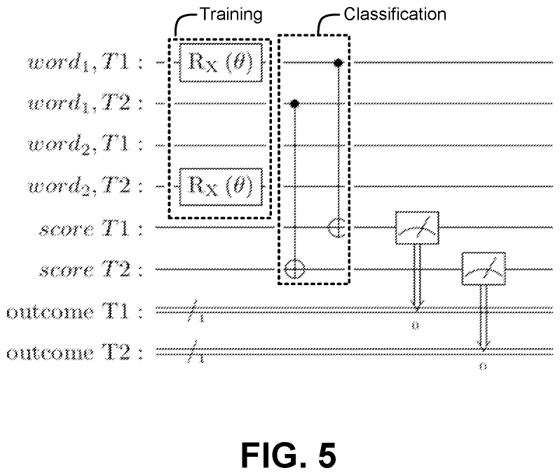

FIG. 5 illustrates an example of a circuit implementation for analyzing training data. In an exemplary aspect, during training, data may be dynamically received and analyzed by computer device 300, such as being stored in data store 340 and analyzed by general controller 205 and/or the algorithms component 210, for example. The training data may include documents and other electronic data related to the particular “bag-of-words” classifier circuit being generated. For example, a document may be a sentence that states “poor visibility with strong wind and rain shuts down tennis parks.” Another document may be a sentence that states “rain and wind causing unfavorable playing conditions.” Yet another document may be a sentence that states “rain expected preventing outdoor activity.” As noted above, the training documents may be generated by various automated systems, sensors, telemetry data, etc., in addition to manually written text by humans. These three training documents may be labelled with “no” as a response to the play tennis question described previously. A bag of words generated for the response “no” may include {poor (1), visibility (1), with (1), strong (1), wind (2), and (2), rain (3), shuts (1), down (1), tennis (1), parks (1), causing (1), unfavorable (1), playing (1), conditions (1), expected (1), preventing (1), outdoor (1), activity (1)}, which includes the word followed by word count in the documents. For example, the word “rain” appears three times, which suggests a strong correlation with being unable to play tennis. Similarly, there may be training documents with words that indicate favorable conditions for playing tennis. Such words may include sunny, overcast, normal, etc. For any arbitrary input such as “tomorrow is a sunny day with normal humidity,” computer device 300 is configured to determine whether the input corresponds to the bag of words labelled “no” (e.g., no to the question of playing tennis) or corresponds to the bag of words labelled “yes” (e.g., yes to the question of playing tennis). In this case, computer device 300 may determine each probability of the correspondence to the first bag of words and the second bag of words. Computer device 300 may then compare the probabilities and output the label with the highest probability. For example, for the input “tomorrow is a sunny day with normal humidity,” computer device 300 may determine that the output label should be “yes.”

In a classification model, each word has a particular weight in the complete dictionary, where the weight is relative to the topic. This weight is learned by training the classification model. In FIG. 5, for example, T1 may be “yes” and T2 may be “no.” Suppose that word₁ is “sunny” and word₂ is “rain.” The weight of the word “sunny” should be higher for T1 than T2 because there is a greater likelihood that the presence of the word “sunny” in an input sentence implies that the answer to playing tennis is “yes.” The weight of the word “rain” should be higher for T2 than T1 because there is a greater likelihood that the presence of the word “rain” in an input sentence implies that the answer to playing tennis is “no.”

When applied to a quantum circuit, a weight/angle that reflects how often each word was seen with each topic is stored in the corresponding qubit. That is, the more a word appears in the training data, the greater the rotation angle will be applied to the qubit gate to effectively assign a higher weighted value. Moreover, when classifying a new phrase, computer device 300 may add CNOT gates to connect the words in a phrase with the appropriate topic-scoring qubit. A classifier trained in this way may accurately predict all of the topic labels. For example, all words in a particular input phrase are mapped to the dictionary, the rotation angles are applied, and the scores are summed and observed.

In the exemplary aspect of FIG. 5, the two CNOT gates effectively accumulate the classifier weights. As such, the system is configured to add them up in a nonlinear fashion as the scores T1 and T2 and observe them as outcomes T1 and T2. In this case, the greatest value between outcomes T1 and T2 is the response to the question. Moreover, it should be clear that the word₁ T1 at the top that gets a bit of a rotation because the word was identified many times in the training data (in this example). In contrast, the word₁ T2 qubit does not get a rotation from the training data, as word₁ is not necessarily relevant to topic T2.

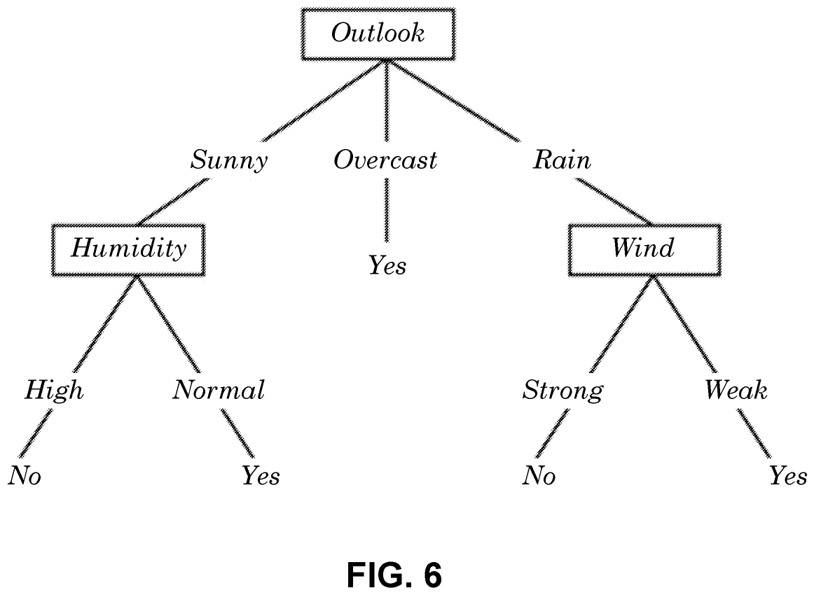

In another exemplary aspect, sophisticated classification may need a combination of individual features. FIG. 6 illustrates an example of a decision tree that may be implemented by a quantum circuit.

In the example shown in FIG. 6, the quantum circuit is configured to determine, for example, that the “Outlook” is “Sunny” AND the “Humidity” is “Normal” to decide to play tennis. This question is effectively implemented as a decision tree that is a Boolean function/logical proposition, which uses the observation that each path down the tree is a conjunction of attribute values (e.g., OUTLOOK==Sunny && WIND==Light && HUMIDITY==Normal→Play Tennis). Moreover, since any path will do, the tree as a whole may be represented as a disjunction of conjunctions.

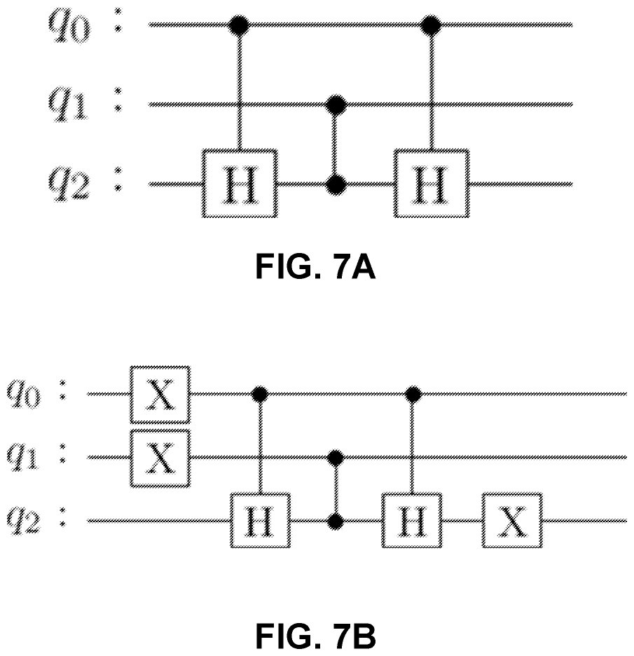

According to the exemplary system and method described herein, the question “how may we implement a quantum decision tree circuit?” may be transformed to a question: “can a quantum circuit represent the disjunction of a list of conjunctions?”, which may be achieved using circuit/gate formulas as described herein. For example, FIG. 7A illustrates an example quantum circuit implementation of Boolean connectives as an AND conjunction circuit. FIG. 7B illustrates another example quantum circuit implementation of Boolean connectives in which the OR disjunction is the same implementation surrounded by suitable negations. It should be noted that these quantum circuit implementations are exemplary configurations that have the fewest 2-qubit gates, but that such circuits may be implemented using alternative quantum circuits, as would be appreciated to one skilled in the art.

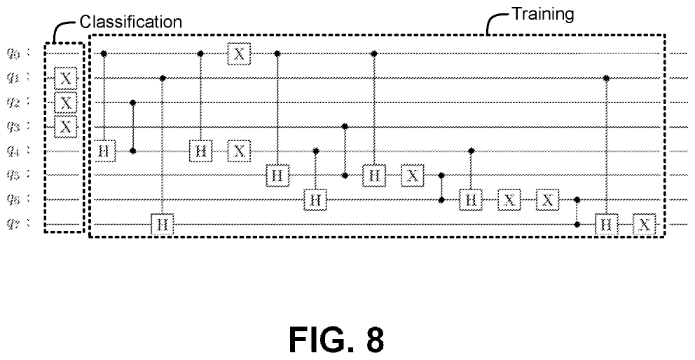

FIG. 8 illustrates a complete quantum circuit that implements the Play Tennis decision tree shown in FIG. 6. In this case, the “training” or “compilation” phase creates the quantum circuit to the right, and the classification phase initializes the input qubits to particular values. In other words, the X gates are determined based on the training and combined into a quantum circuit that implements the decision tree of FIG. 6, for example. As such, the training rectangle is a quantum circuit implementation for precisely the decision tree described above according to an exemplary aspect.

The exemplary implementation shown in FIG. 8 is a classical algorithm used to infer an optimal list of conjunctions to encode in the decision tree. In turn, computer device 300 may be configured to use this list of conjunctions to compile this reduced form into a quantum circuit by setting the rotation and angles θ as described above.

According to an additional exemplary aspect, computer device 300 may also be configured to encode training examples themselves into the quantum circuit. Effectively, any “training” (using training data, for example) is also performed in the quantum circuit, which may be referred to as a “superposition of conjunctions classifier” for purposes of the present disclosure. In particular, computer device 300 may be configured to use multi-controlled gates with custom qubit operations that are configured to be performed on the target bit(s). Effectively, this implementation is a complement of the addition circuits described above: instead of connecting partially rotated inputs to control a complete X-gate rotation output, computer device 300 may use completely rotated inputs to control a partial rotation as an output.

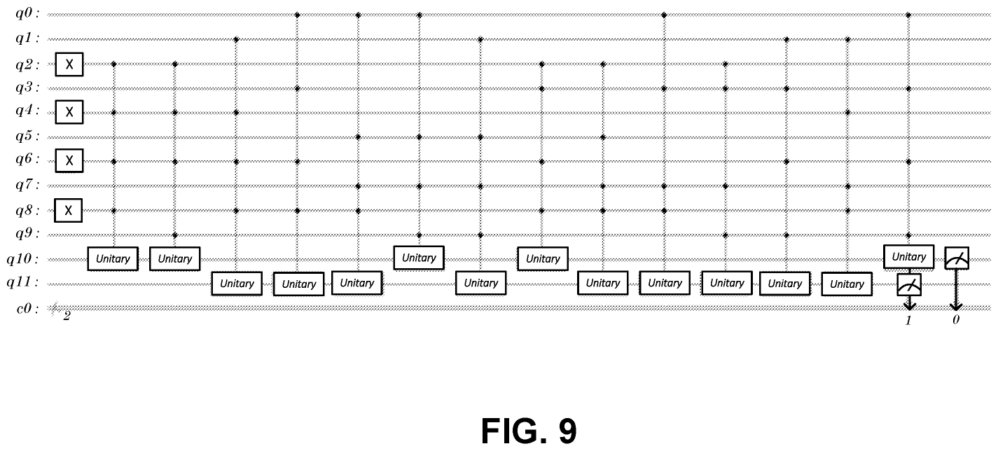

FIG. 9 illustrates an example circuit of a superposition of conjunctions classifier. In particular, by setting the Unitary to be a fractional X rotation through angle π/12, computer device 300 may be configured to output accurate results on all example input combinations for the Play Tennis decision tree, through a complete X rotation.

Yet further, computer device 300 may be configured to adapt the superposition classifier to use parts of conjunctions according to an exemplary aspect. For example, if a training example says “Overcast and Mild and Light wind implies Play Tennis,” computer device 300 may be configured to infer that Overcast and Mild probably implies Play Tennis, and may add this information and combinatorial variants to the quantum circuit. For example, more generally speaking, if A and B and C was one of the examples of training data, then computer device 300 may be configured to add a target angle θ for the combination of A and B and C, where the combinations “A, and B, A” and “C, B, and C” are added with target angle θ/2, and the single contributions “A, B, C” are added with target angle θ/4. The differences in rotation value reflect the proportional weighted values for each qubit. That is, the different size rotations applied to the various gates are not just for individual features, but also applied to the combinations of features.

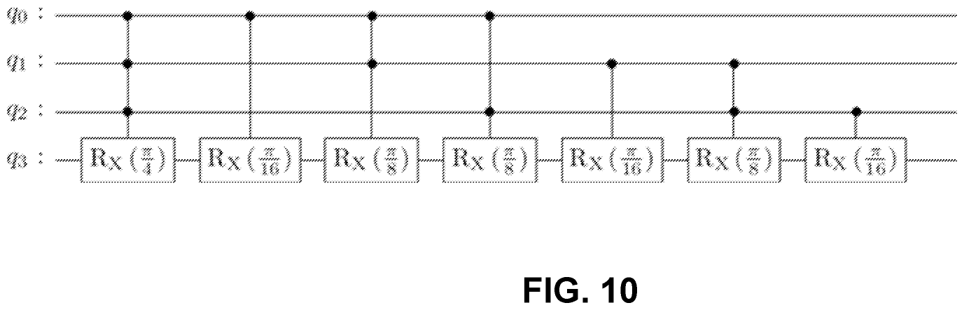

FIG. 10 illustrates an example of the code for an implementation being in the “include_subclauses” conditional expression.

Effectively, the classifier may be more robust to partial inputs, giving measurable improvements compared with both a random baseline, and more importantly, over the default implementation in decision trees. For example, full or small datasets for decision trees are provided and, for each of 100 runs, are split randomly (75% training, 25% testing), wherein the sklearn decision tree is training and a superposition of conjunctions classifier is applied using the 75% train data with the classifier being applied to the remaining 25% test data. The combination of the results from these runs and measurement of accuracy is shown below based on a real test:

| | Sklearn Decision tree | Superposition of |
|---|---|---|
| Dataset | Results | Conjunctions Results |
| “Play tennis” dataset | Attempted 400 | Attempted 400 |
| 14 rows, 4 attributes | Correct 220 | Correct 235 |
| | Accuracy 0.55 | Accuracy 0.588 |
| “Play tennis” small | Attempted 300 | Attempted 300 |
| dataset | Correct 161 | Correct 182 |
| 12 rows, 3 attributes | Accuracy 0.537 | Accuracy 0.607 |

As shown, the accuracy is significantly increased, especially for the smaller dataset using the superposition of conjunctions classifier.

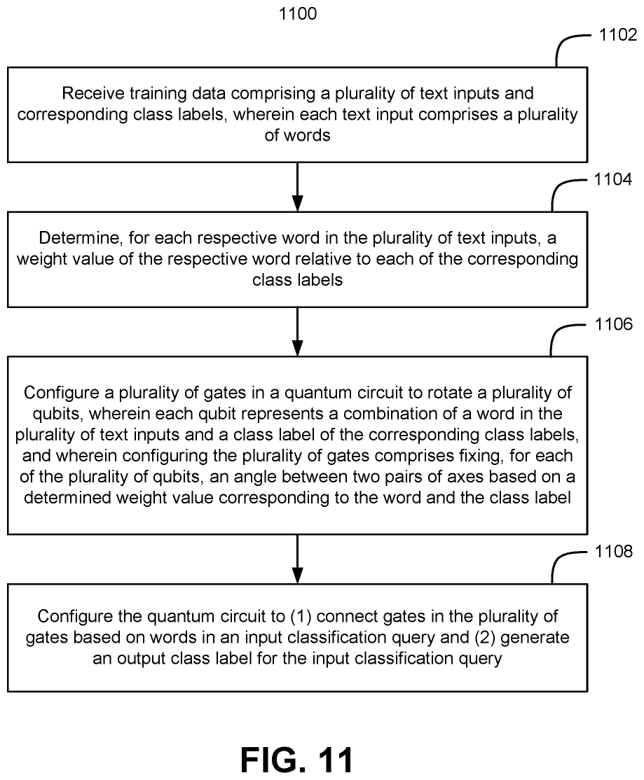

FIG. 11 illustrates a method 1100 for configuring a quantum circuit comprising a plurality of qubits to implement classification in accordance with aspects of the present disclosure. The steps and algorithms described in relation to method 1100 may be executed by processor 310 using algorithms component 210. At 1102, computer device 300 receives training data comprising a plurality of text inputs and corresponding class labels, wherein each text input comprises a plurality of words. In some aspects, computer device 300 may store the training data in a data store 340.

At 1104, computer device 300 determines, for each respective word in the plurality of text inputs, a weight value of the respective word relative to each of the corresponding class labels. In some aspects, computer device 300 determines the weight value for each respective word based on a word count of the respective word in text inputs of the respective class label. For example, if the word “rain” appears X amount of times in text inputs tagged with the class label “no,” and the word “sunny” appears Y amount of times in text inputs tagged with the class label “yes,” the weight value of “rain” and “no” will determined based on X and the weight value of “rain” and “yes” will be determined based on Y. For example, the weight value may be given by the ratio of X over the total number of word appearances of “rain” in the text inputs (e.g., X/(X+Y)).

In some aspects, computer device 300 further determines/adjusts the weight value for each respective word by training a bag-of-words classification model using the training data. In some aspects, this training is performed directly using a quantum circuit. For example, the quantum circuit includes a respective classification qubit for each class label of the corresponding class labels. The gates are connected such that a chance of observing a |1> for the respective classification qubit increases with a probability of the respective classification qubit representing a correct class label. Suppose that the weight value for the word “rain” and class “no” is initially set to X. As will be discussed, this weight value is mapped to a rotation angle in step 1106. Suppose that the rotation angle is pi/2. If an input text solely has the word “rain” and the correct output class label is “no,” the output of the quantum circuit should be such that the chance of observing a |1> for the “no” classification qubit is maximized. If the rotation angle of pi/2 does not yield this result, then the rotation angle is iteratively adjusted until the correct output class label is determined. These iterative adjustments also take into account the outcomes of all training data. In this case, computer device 300 trains directly using the inputs and outputs of the quantum circuit and adjusts the rotation angles accordingly.

At 1106, computer device 300 configures a plurality of gates in a quantum circuit to rotate a plurality of qubits, wherein each qubit represents a combination of a word in the plurality of text inputs and a class label of the corresponding class labels, and wherein configuring the plurality of gates comprises fixing, for each of the plurality of qubits, an angle between two pairs of axes based on a determined weight value corresponding to the word and the class label.

For example, a first word (e.g., “sunny”) has a first weight value (e.g., 0.9) for a first class label (e.g., “yes”) and a second weight value (e.g., 0.1) for a second class label (e.g., “no”). Here, the first weight value is greater than the second weight value. Accordingly, when fixing the angle between the two pairs of axes, computer device 300 fixes a first angle (e.g., pi/2) for a qubit associated with a combination of the first word (e.g., “sunny”) and the first class label (e.g., “yes”) and fixing a second angle (e.g., pi/8) for a qubit associated with a combination of the first word (e.g., “sunny”) and the second class label (e.g., “no”). Here, the first angle is greater than the second angle. In some aspects, there may be a function executed by computer device 300 that maps the weight value to a corresponding angle. On a technical level, computer device 300 configures the plurality of gates by applying a laser in Raman configuration of a quantum computer to fix the angles.

At 1108, computer device 300 configures the quantum circuit to (1) connect gates in the plurality of gates based on words in an input classification query and (2) generate an output class label for the input classification query. For example, computer device 300 may receive the input classification query comprising a test text input. The test text input may be generated by a person, an automated system, a sensor, etc. Computer device 300 may then classify the test text input using the configured quantum circuit. In particular, computer device 300 may identify a subset of qubits in the quantum circuit that correspond to each respective word in the test text input. For example, referring to FIG. 5, if word₁ is present in the test text input, computer device 300 identifies the first two qubits corresponding to “word₁, T1” and “word₁, T2.” Computer device 300 may then connect a subset of gates in the quantum circuit that correspond to the subset of qubits. For example, in FIG. 5, CNOT gates are used to connect the first two qubits and determine score T1 and score T2. In some aspects, computer device 300 may use one or more CNOT gates and Toffoli gates to combine two or more partial rotations applied to qubits. Computer device 300 may then execute the quantum circuit to receive the output class label. For example, computer device 300 may observe the results in outcome T1 and outcome T2, with the higher value of the two being an indication of the correct output class label.

In general, it is noted that the foregoing description of the disclosure is provided to enable a person skilled in the art to make or use the disclosure. Various modifications to the disclosure will be readily apparent to those skilled in the art, and the common principles defined herein may be applied to other variations without departing from the scope of the disclosure. Furthermore, although elements of the described aspects may be described or claimed in the singular, the plural is contemplated unless limitation to the singular is explicitly stated. Additionally, all or a portion of any aspect may be utilized with all or a portion of any other aspect, unless stated otherwise. Thus, the disclosure is not to be limited to the examples and designs described herein but is to be accorded the widest scope consistent with the principles and novel features disclosed herein.

What is claimed is:

1. A method for configuring a quantum circuit having a plurality of qubits to implement a classification, the method comprising:
receiving training data comprising a plurality of text inputs and corresponding class labels, wherein each text input comprises a plurality of words;
determining, for each respective word in the plurality of text inputs, a weight value of the respective word relative to each of the corresponding class labels;
configuring a plurality of gates in the quantum circuit to rotate the plurality of qubits, wherein each qubit represents a combination of a word in the plurality of text inputs and a class label of the corresponding class labels, and wherein configuring the plurality of gates comprises fixing, for each of the plurality of qubits, an angle between two pairs of axes based on a determined weight value corresponding to the word and the class label; and
configuring the quantum circuit to (1) connect gates in the plurality of gates based on words in an input classification query and (2) generate an output class label for the input classification query.

2. The method of claim 1, further comprising:
receiving the input classification query comprising a test text input; and
classifying the test text input using the configured quantum circuit.

3. The method of claim 2, wherein classifying the test text input comprises:
identifying a subset of qubits in the quantum circuit that correspond to each respective word in the test text input;
connecting a subset of gates in the quantum circuit that correspond to the subset of qubits; and
executing the quantum circuit to receive the output class label.

4. The method of claim 3, wherein connecting the subset of gates comprises using one or more CNOT gates and Toffoli gates to combine two or more partial rotations.

5. The method of claim 1, wherein the quantum circuit comprises a respective classification qubit for each class label of the corresponding class labels, wherein the gates are connected such that a chance of observing a |1> for the respective classification qubit increases with a probability of the respective classification qubit representing a correct class label.

6. The method of claim 1, wherein a first word has a first weight value for a first class label and a second weight value for a second class label, wherein the first weight value is greater than the second weight value, and wherein fixing the angle between the two pairs of axes comprises fixing a first angle for a qubit associated with a combination of the first word and the first class label and fixing a second angle for a qubit associated with a combination of the first word and the second class label, wherein the first angle is greater than the second angle.

7. The method of claim 1, wherein determining the weight value for each respective word is based on a word count of the respective word in text inputs of the respective class label.

8. The method of claim 1, wherein determining the weight value for each respective word comprises training a bag-of-words classification model using the training data.

9. The method of claim 1, wherein configuring the plurality of gates comprises applying a laser in Raman configuration of a quantum computer to fix the angle.

10. The method of claim 1, further comprising storing the training data in a data store of a quantum computer.

11. A quantum information processing (QIP) system comprising:
at least one memory; and
at least one hardware processor coupled with the at least one memory and configured, individually or in combination, to:
receive training data comprising a plurality of text inputs and corresponding class labels, wherein each text input comprises a plurality of words;
determine, for each respective word in the plurality of text inputs, a weight value of the respective word relative to each of the corresponding class labels;
configure a plurality of gates in a quantum circuit to rotate a plurality of qubits, wherein each qubit represents a combination of a word in the plurality of text inputs and a class label of the corresponding class labels, and wherein configuring the plurality of gates comprises fixing, for each of the plurality of qubits, an angle between two pairs of axes based on a determined weight value corresponding to the word and the class label; and
configure the quantum circuit to (1) connect gates in the plurality of gates based on words in an input classification query and (2) generate an output class label for the input classification query.

12. The QIP system of claim 11, wherein the at least one hardware processor is further configured to:
receive the input classification query comprising a test text input; and
classify the test text input using the configured quantum circuit.

13. The QIP system of claim 12, wherein the at least one hardware processor is further configured to classify the test text input by:
identifying a subset of qubits in the quantum circuit that correspond to each respective word in the test text input;
connecting a subset of gates in the quantum circuit that correspond to the subset of qubits; and
executing the quantum circuit to receive the output class label.

14. The QIP system of claim 13, wherein the at least one hardware processor is further configured to connect the subset of gates by using one or more CNOT gates and Toffoli gates to combine two or more partial rotations.

15. The QIP system of claim 1, wherein the quantum circuit comprises a respective classification qubit for each class label of the corresponding class labels, wherein the gates are connected such that a chance of observing a |1> for the respective classification qubit increases with a probability of the respective classification qubit representing a correct class label.

16. The QIP system of claim 1, wherein a first word has a first weight value for a first class label and a second weight value for a second class label, wherein the first weight value is greater than the second weight value, and wherein fixing the angle between the two pairs of axes comprises fixing a first angle for a qubit associated with a combination of the first word and the first class label and fixing a second angle for a qubit associated with a combination of the first word and the second class label, wherein the first angle is greater than the second angle.

17. The QIP system of claim 11, wherein the at least one hardware processor is further configured to determine the weight value for each respective word based on a word count of the respective word in text inputs of the respective class label.

18. The QIP system of claim 11, wherein the at least one hardware processor is further configured to determine the weight value for each respective word by training a bag-of-words classification model using the training data.

19. The QIP system of claim 11, wherein the at least one hardware processor is further configured to configure the plurality of gates by applying a laser in Raman configuration of a quantum computer to fix the angle.

20. The QIP system of claim 11, wherein the at least one hardware processor is further configured to store the training data in a data store of a quantum computer.
